(19) United States
(12) Patent Application Publication
(10) Pub. No.: US 2025/0246466 A1
(43) Pub. Date: Jul. 31, 2025

(54) ALIGNMENT FIXTURE FOR A REACTOR SYSTEM

(71) Applicant: ASM IP Holding B.V., Almere (NL)

(72) Inventors: Surojit Ganguli, Phoenix, AZ (US); Todd Robert Dunn, Cave Creek, AZ (US); Ankit Kimtee, Phoenix, AZ (US)

(21) Appl. No.: 19/076,501

(22) Filed: Mar. 11, 2025

Related U.S. Application Data
(62) Division of application No. 17/190,615, filed on Mar. 3, 2021, now Pat. No. 12,278,129.
(60) Provisional application No. 62/985,184, filed on Mar. 4, 2020.

(51) Int. Cl. H01L 21/68; C23C 16/455; C23C 16/458; H01L 21/67; H01L 21/687

(52) U.S. Cl. CPC H01L 21/68; C23C 16/45544; C23C 16/4583; H01L 21/67259; H01L 21/68735; H01L 21/67069

(57) ABSTRACT

An alignment fixture for a reactor system may comprise a fixture body comprising an inner perimeter at least partially defining a shape which comprises an inner space of the fixture body, wherein the inner space is configured to receive a susceptor of a reactor system; and/or a measuring protrusion coupled to the fixture body at a first position and protruding from the fixture body toward the inner space. The measuring protrusion may comprise an indicator between the fixture body and a measuring protrusion end of the measuring protrusion.

### CROSS-REFERENCE TO RELATED APPLICATIONS

This application is a divisional of, and claims priority to and the benefit of, U.S. patent application Ser. No. 17/190,615, filed Mar. 3, 2021 and entitled, “ALIGNMENT FIXTURE FOR A REACTOR SYSTEM,” which is a non-provisional of, and claims priority to and the benefit of, U.S. Provisional Patent Application No. 62/985,184, filed Mar. 4, 2020 and entitled “ALIGNMENT FIXTURE FOR A REACTOR SYSTEM,” both of which are hereby incorporated by reference herein.

### FIELD OF THE DISCLOSURE

The present disclosure generally relates to an alignment fixture for positioning a component within a reactor system.

### BACKGROUND

Reaction chambers may be used for depositing various material layers onto semiconductor substrates. A semiconductor may be placed on a susceptor inside a reaction chamber. Both the substrate and the susceptor may be heated to a desired substrate temperature set point. In an example substrate treatment process, one or more reactant gases may be passed over a heated substrate, causing the deposition of a thin film of material on the substrate surface. Throughout subsequent deposition, doping, lithography, etch, and other processes, these layers can be used in the formation of integrated circuits.

To achieve desired results on the substrate (e.g., uniform or robust deposition of a film on the substrate), the susceptor and/or substrate may be disposed within the reaction chamber in a certain position. For example, the susceptor may be disposed, such that there is a desired space between the susceptor and sidewall of the reaction chamber (e.g., a uniform space resulting from the susceptor being centered within the reaction chamber). Such positioning may prevent uneven processing of the substrate within the reaction chamber, and may facilitate achieving desired results. However, achieving the desired position of the susceptor or other components in a reaction chamber may be difficult, and errors in such positioning may cause undesirable processing outcomes.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In various embodiments, an alignment fixture for a reactor system is provided. The alignment fixture disclosed herein may comprise a fixture body comprising an inner perimeter at least partially defining a shape which comprises an inner space of the fixture body, wherein the inner space is configured to receive a susceptor of a reactor system; and/or a measuring protrusion coupled to the fixture body at a first position and protruding from the fixture body toward the inner space. The measuring protrusion may comprise an indicator between the fixture body and a measuring protrusion end of the measuring protrusion. In various embodiments, the fixture body may further comprise an outer perimeter opposite the inner perimeter, wherein the outer perimeter defines an outer shape of the fixture body. In various embodiments, the shape at least partially defined by the inner perimeter may be complementary to a shape of the susceptor, which the inner space is configured to receive therein. In various embodiments, the fixture body further may comprise an upper surface, wherein the measuring protrusion may be coupled to the upper surface of the fixture body and protrude toward the inner space.

In various embodiments, the measuring protrusion may comprise a first plurality of graduation marks disposed between the fixture body and the measuring protrusion end of the measuring protrusion, wherein the first plurality of graduation marks comprises the indicator. In various embodiments, the alignment fixture may further comprise a second measuring protrusion protruding from the fixture body at a second position toward the inner space. The second measuring protrusion may comprise a second indicator between the fixture body and a second measuring protrusion end of the second measuring protrusion. In various embodiments, the first measuring protrusion and the second measuring protrusion may extend toward a center of the shape at least partially defined by the inner perimeter. The indicator may be disposed on the first measuring protrusion a first distance from the inner perimeter of the fixture body, and the second indicator may be disposed on the second measuring protrusion a second distance from the inner perimeter of the fixture body. In various embodiments, the first distance and the second distance may be the same.

In various embodiments, a reactor system may comprise a susceptor comprising a susceptor outer edge, wherein the susceptor may be configured to receive a substrate thereon; a spacer plate comprising a plate interior space defined by a spacer plate inner wall, wherein the susceptor may be disposed at least partially in the plate interior space, wherein the susceptor and spacer plate may be disposed relative to one another such that there is a gap between the susceptor outer edge and the spacer plate inner wall; and an alignment fixture disposed at least partially within the gap between the susceptor outer edge and the spacer plate inner wall. The alignment fixture may comprise a fixture body comprising an inner perimeter at least partially defining a shape which comprises an inner space of the fixture body, wherein the susceptor is disposed at least partially within the inner space; and/or a measuring protrusion protruding from the fixture body at a first position toward the inner space, wherein the measuring protrusion may comprise an indicator between the fixture body and a measuring protrusion end of the measuring protrusion. In various embodiments, the inner perimeter of the fixture body may be spaced from the susceptor outer edge, such that the inner perimeter of the fixture body is not in contact with the susceptor outer edge. In various embodiments, the measuring protrusion may extend over the susceptor outer edge.

In various embodiments, the fixture body may further comprise an outer perimeter opposite the inner perimeter, wherein the outer perimeter defines an outer shape of the fixture body, which may be complementary to a shape of the plate interior space. In various embodiments, the fixture body may further comprise an upper surface disposed on an upper plane of the alignment fixture. The measuring protrusion may be coupled to the upper surface of the fixture body and may protrude toward the inner space, and the susceptor may be disposed below the upper plane.

In various embodiments, the measuring protrusion may comprise a first plurality of graduation marks disposed between the fixture body and the measuring protrusion end of the measuring protrusion, wherein the first plurality of graduation marks comprises the indicator. In various embodiments, the alignment fixture may further comprise a second measuring protrusion protruding from the fixture body at a second position toward the inner space, wherein the second measuring protrusion may comprise a second indicator between the fixture body and a second measuring protrusion end of the second measuring protrusion. In various embodiments, the first measuring protrusion and the second measuring protrusion may extend toward a center of the shape at least partially defined by the inner perimeter. The indicator may be disposed on the first measuring protrusion a first distance from the inner perimeter of the fixture body, and the second indicator may be disposed on the second measuring protrusion a second distance from the inner perimeter of the fixture body. In various embodiments, the first distance and the second distance may be the same.

In various embodiments, reactor system may further comprise a reaction chamber, in which the susceptor, the spacer plate and the alignment fixture are at least partially disposed.

In various embodiments, a method may comprise disposing an alignment fixture at least partially within an area between a susceptor outer edge of a susceptor and a spacer plate inner wall of a spacer plate of a reactor system, wherein the susceptor is disposed within an inner space of the alignment fixture at least partially defined by an inner perimeter of the alignment fixture, wherein a measuring protrusion protruding from a fixture body of the alignment fixture is disposed over the outer edge of the susceptor; and/or adjusting a position of the susceptor such that the susceptor is disposed in a desired position relative to the inner perimeter of the alignment fixture. In various embodiments, the alignment fixture may comprise a second measuring protrusion protruding from the fixture body. Aligning the susceptor may comprise positioning the susceptor such that the susceptor is positioned the same distance along the first measuring protrusion relative to the inner perimeter of the alignment fixture as along the second measuring protrusion relative to the inner perimeter of the alignment fixture.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWINGS

The subject matter of the present disclosure is particularly pointed out and distinctly claimed in the concluding portion of the specification. A more complete understanding of the present disclosure, however, may best be obtained by referring to the detailed description and claims when considered in connection with the drawing figures, wherein like numerals denote like elements.

FIG. 1 illustrates a schematic diagram of a reactor system, in accordance with various embodiments.

FIGS. 2A and 2B illustrate perspective views of an alignment fixture for a reactor system, in accordance with various embodiments.

FIG. 3A illustrates an exploded view of components of a reaction chamber with an alignment fixture, in accordance with various embodiments.

FIG. 3B illustrates a reactor system with an alignment fixture, in accordance with various embodiments.

FIG. 4 illustrates a method for positioning a susceptor in a reaction chamber, in accordance with various embodiments.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” may refer to any underlying material or materials that may be used, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. During each cycle the precursor may be chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. This reactant may be capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As used herein, the term “gas” may include vaporized solid and/or liquid and may be constituted by a single gas or a mixture of gases.

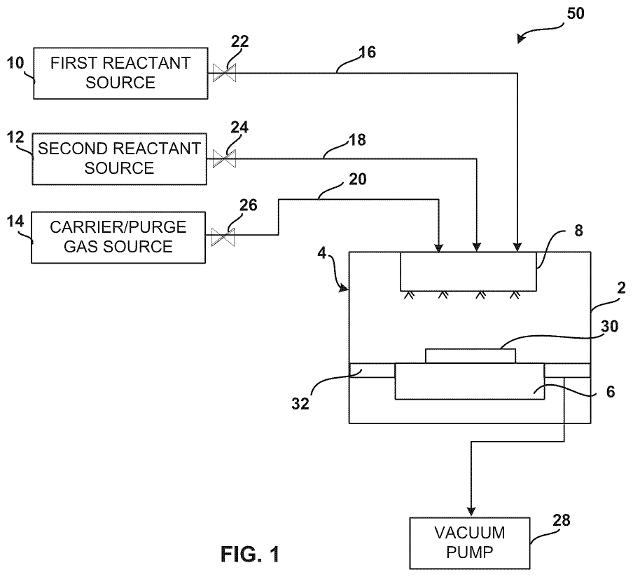

Reactor systems used for ALD, CVD, and/or the like, may be used for a variety of applications, including depositing and etching materials on a substrate surface. In various embodiments, with reference to FIG. 1, a reactor system 50 may comprise a reaction chamber 4, a susceptor 6 to hold a substrate 30 during processing, a gas distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20, and valves or controllers 22-26. In various embodiments, a susceptor (e.g., susceptor 6) may comprise and/or be coupled to a temperature control device (e.g., a heater or cooling device). Reactant gases or other materials from reactant sources 10, 12 may be applied to substrate 30 in reaction chamber 4. A purge gas from purge gas source 14 may be flowed to and through reaction chamber 4 to remove any excess reactant or other undesired materials from reaction chamber 4. System 50 may also comprise a vacuum source 28 fluidly coupled to the reaction chamber 4, which may be configured to suck reactants, a purge gas, and/or other materials out of reaction chamber 4.

In various embodiments, to achieve desired results from a process within a reaction chamber (e.g., material deposition or etching on a substrate), the susceptor (e.g., susceptor 6) may be disposed within the reaction chamber in a certain position. For example, to achieve uniform material deposition on and across a substrate, the susceptor may be positioned in the center of the reaction chamber, such that the side(s) of the susceptor are uniformly spaced from the interior sidewall(s) of the reaction chamber. If such spacing between the susceptor and the reaction chamber interior side walls is not uniform, one portion of the substrate may be subjected to a greater amount of reactant gas within the reaction chamber than another portion of the substrate, cause non-uniform material deposition (i.e., an undesirable result).

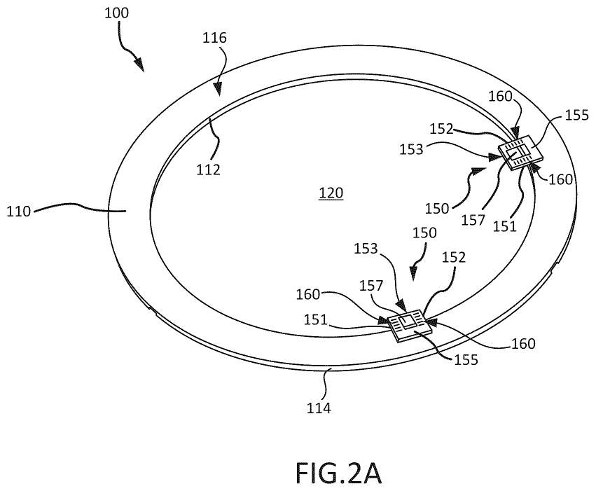

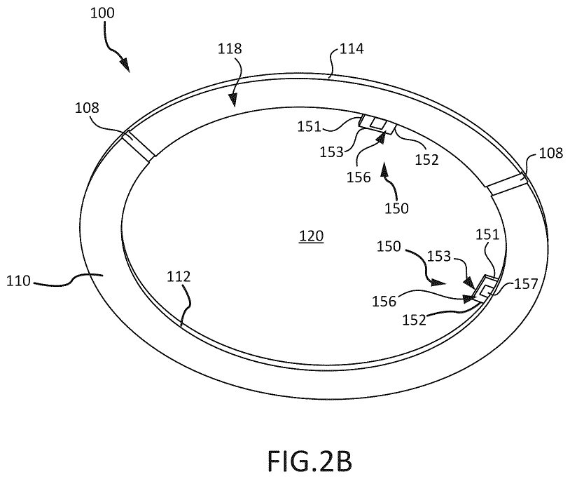

To aid in achieving a desired position of the susceptor within a reaction chamber, an alignment fixture may be used. With reference to FIGS. 2A and 2B, an alignment fixture 100 is depicted in accordance with various embodiments. An alignment fixture may comprise a fixture body having an inner perimeter, an outer perimeter, an upper surface, and a lower surface. For example, alignment fixture 100 may comprise inner perimeter 112, outer perimeter 114 opposite inner perimeter 112, upper surface 116, and/or lower surface 118 opposite upper surface 116. Fixture body 110 of alignment fixture 100 may be disposed between inner perimeter 112 and outer perimeter 114, and between upper surface 116 and lower surface 118. The inner perimeter of an alignment fixture may at least partially define a shape. The shape at least partially defined by the inner perimeter of an alignment fixture may comprise an inner space of the alignment fixture. The inner space of an alignment fixture may be configured to receive a susceptor in a reaction chamber. That is, the inner perimeter of an alignment fixture may be configured to at least partially encircle or enclose a susceptor in a reaction chamber in response to the alignment fixture being disposed therein. For example, inner space 120 defined by inner perimeter 112 of alignment fixture 100 may be configured to receive a susceptor in a reaction chamber.

As depicted in FIGS. 2A and 2B, alignment fixture 100 and/or inner perimeter 112 comprise or define a circular shape comprising inner space 120, but an alignment fixture, inner space, and/or the shape at least partially defined by the inner perimeter of an alignment fixture may comprise any suitable shape. For example, an alignment fixture and/or an inner perimeter of an alignment fixture may comprise or at least partially define a hexagon, octagon, rectangle, a portion of a shape, or any other suitable shape. For example, an alignment fixture and/or inner perimeter thereof may comprise or define a semicircle or quarter-circle (e.g., half or a quarter of alignment fixture 100). In embodiments in which the inner perimeter of an alignment fixture comprises or defines a portion of a shape, such as a semicircle (i.e., the inner space of an alignment fixture is not completely enclosed by the fixture body), the shape at least partially defined by the alignment fixture inner perimeter is said to be the full shape (e.g., a circle), and the inner space of the alignment fixture may be comprised therein.

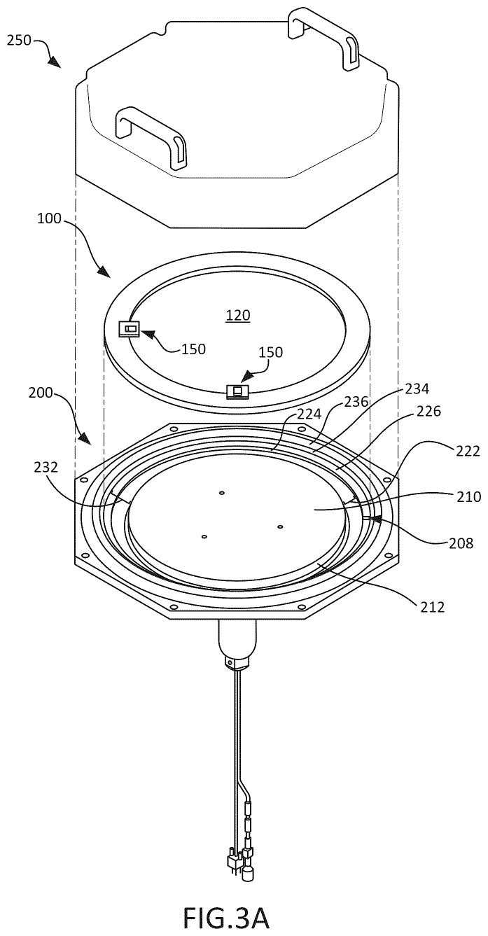

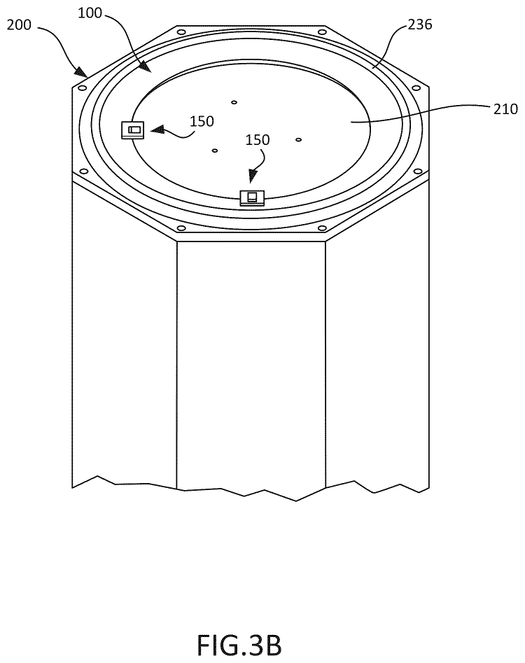

In various embodiments, the shape of the susceptor configured to be received in the inner space of an alignment fixture may be complementary to the shape at least partially defined by the alignment fixture inner perimeter. With additional reference to FIG. 3A, susceptor 210 may comprise an outer edge 212 defining a shape of susceptor 210. The circular shape of susceptor 210 may be complementary to the circular shape of inner space 120 defined by inner perimeter 112.

In various embodiments, an alignment fixture may comprise one or more measuring protrusions (e.g., measuring protrusions 150 in FIGS. 2A and 2B). The measuring protrusion may extend or protrude from the fixture body toward the inner space of the alignment fixture. The measuring protrusion may extend from the fixture body and cross the alignment fixture inner perimeter toward and/or into the inner space. For example, measuring protrusions 150 may protrude from fixture body 110 across inner perimeter 112 toward and/or into inner space 120. In various embodiments, a measuring protrusion may extend from the fixture body toward a center of the shape at least partially defined by the inner perimeter of the fixture body. For example, measuring protrusions 150 may extend from fixture body 110 toward a center of the circle defined by inner perimeter 112 (or the center of inner space 120).

In various embodiments, a measuring protrusion may be coupled to the fixture body and/or be integral or monolithic with the fixture body. The measuring protrusion may be coupled to the upper surface, lower surface, and/or inner perimeter of the fixture body (e.g., upper surface 116, lower surface 118, and/or inner perimeter 112 of fixture body 110). In various embodiments, the upper surface of the alignment fixture may be disposed on an upper plane, and the lower surface of the alignment fixture may be disposed on a lower plane. A measuring protrusion of the alignment fixture may be coupled to the upper surface and extend toward the inner space without traversing the upper plane.

The measuring protrusion(s) of an alignment fixture may comprise any suitable shape. For example, a measuring protrusion may comprise an oval, rectangular, square, or any other polygonal shape having a measuring protrusion end being the portion of the measuring protrusion furthest from the inner perimeter of the fixture body and furthest into the inner space of the alignment fixture. For example, measuring protrusions 150 may comprise a rectangular shape having a first side 151, a second side 152, a protrusion body 155 therebetween, and a measuring protrusion end 153. In various embodiments, a measuring protrusion body may be solid having no voids therein or therethrough.

In various embodiments, a measuring protrusion may comprise a protrusion void through a portion of the protrusion body. The protrusion void may be at least partially enclosed within the protrusion body. For example, protrusion void 157 may be completely enclosed within protrusion body 155. As another example, the protrusion void may be partially enclosed by the protrusion body such that a portion of the protrusion void may be in fluid communication with the inner space of the alignment fixture. For example, at least a portion of the measuring protrusion end may be separated by the protrusion void (e.g., such that the measuring protrusion may be forked). In embodiments in which a measuring protrusion comprises a protrusion void, the measuring protrusion may comprise multiple prongs (e.g., a first prong and a second prong). For example, measuring protrusions 150 may comprise a first prong comprising first side 151 and a second prong comprising second side 152.

In various embodiments, an alignment fixture may comprise multiple measuring protrusions. For example, multiple measuring protrusions may be coupled to a fixture body and disposed along the inner perimeter of the fixture body. The multiple measuring protrusions may be equidistantly spaced along at least a portion of the alignment fixture. In various embodiments, two alignment fixtures (of multiple alignment fixtures, i.e., two or more) may be about 30, 45, 60, 90, 120, 135, 160, and/or 180 degrees apart from one another. As shown in FIGS. 2A and 2B, measuring protrusions are about 90 degrees apart relative to a center of the shape defined by inner perimeter 112. In this context, “about” means plus or minus five degrees.

In various embodiments, a measuring protrusion may comprise an indicator disposed on the protrusion body between the fixture body and the measuring protrusion end. The indicator may be disposed on an upper surface of the measuring protrusion. A measuring protrusion may comprise a plurality of indicators. For example, the plurality of indicators may comprise graduation marks spanning a graduated length between the fixture body and the measuring protrusion end. Graduation marks may be equidistant from one another over the graduated length. In various embodiments, a measuring protrusion may comprise multiple pluralities of indicators, such as one plurality of indicators proximate to each side (and/or on each prong). For example, measuring protrusions 150 may comprise pluralities of indicators 160. Each measuring protrusion 150 may comprise a plurality of indicators 160 proximate first side 151 and/or second side 152. In various embodiments, an indicator or plurality of indicators may be disposed on a measuring protrusion proximate a side of a protrusion void.

The indicator or plurality of indicators may comprise any suitable design, position, and/or arrangement on or in a measuring protrusion. For example, the indicator or plurality of indicators may comprise a line on, or notch or recess into, the protrusion body of the measuring protrusion. For example, each indicator in the pluralities of indicators 160 may be substantially perpendicular from a side of measuring protrusion 150 (e.g., first side 151 and/or second side 152), an axis along which measuring protrusion 150 extends into inner space 120, and/or an axis spanning through measuring protrusion 150 extending toward a center of the shape at least partially defined by inner perimeter 112 (as used herein, “substantially” means plus or minus 10 degrees from perpendicular). In various embodiments, a unit of measurement may be disposed proximate one or more indicators (e.g., millimeters, centimeters, inches, or the like).

In various embodiments, a susceptor of a reactor system may be disposed on and/or in, and/or coupled to, a spacer plate (e.g., as shown in FIGS. 3A and 3B, susceptor 210 may be disposed on and/or in, and/or coupled to, spacer plate 200). A spacer plate (e.g., spacer plate 200) may comprise various inner walls and/or inner surfaces. In various embodiments, a spacer plate (e.g., spacer plate 200) may comprise a spacer plate first inner surface (e.g., spacer plate first inner surface 226) and a spacer plate first inner wall (e.g., spacer plate first inner wall 224). There may be a lower area (e.g., lower area 222) or gap between the outer edge of the susceptor (e.g., susceptor outer edge 212) and the spacer plate first inner wall (e.g., spacer plate first inner wall 224). The lower area may have a lower area floor, which may be a surface of the spacer plate. A spacer plate (e.g., spacer plate 200) may further comprise a spacer plate second inner surface (e.g., spacer plate second inner surface 236) and a spacer plate second inner wall (e.g., spacer plate second inner wall 234). There may be an upper area (e.g., upper area 232) or gap between the outer edge of the susceptor (e.g., susceptor outer edge 212) and the spacer plate second inner wall (e.g., spacer plate second inner wall 234). The width of the upper area (the distance between the spacer plate second inner wall and the susceptor outer edge) comprises the length of the lower area (the distance between the spacer plate first inner wall and the susceptor outer edge).

In various embodiments, an alignment fixture may be disposed onto or into, and/or coupled to, a spacer plate of a reactor system. The alignment fixture may be so disposed or so coupled such that the alignment fixture is at least partially in an area between an inner wall of the spacer plate (e.g., the first or second inner wall) and the outer edge of the susceptor. For example, as shown in FIGS. 3A and 3B, alignment fixture 100 may be disposed on or in, and/or coupled to, spacer plate 200 such that alignment fixture 100 is at least partially in upper area 232 (and/or lower area 222) between an inner wall of spacer plate 200 (e.g., second inner wall 234) and susceptor outer edge 212. In various embodiments, the outer perimeter of the fixture body may be disposed proximate, adjacent to, and/or contiguous with the an inner wall of the spacer plate. For example, as shown in FIGS. 3A and 3B, outer perimeter 114 of alignment fixture 100 may be disposed proximate, adjacent to, and/or contiguous with second inner wall 234 of spacer plate 200.

In various embodiments, an alignment fixture may comprise a thickness (a distance between the inner perimeter and outer perimeter of the fixture body) that is less than an area of the spacer plate between a spacer plate inner wall the outer edge of the susceptor. For example, as depicted in FIGS. 3A and 3B, the thickness of alignment fixture 100 between inner perimeter 112 and outer perimeter 114 may be less or thinner than the thickness of upper area 232 of spacer plate 200. Accordingly, the alignment fixture may be disposed in or on, and/or coupled to, the spacer plate with the susceptor at least partially in the inner space of the alignment fixture, without the susceptor being in contact with the alignment fixture (e.g., the alignment fixture inner perimeter). That is, for example, there may be a gap between inner perimeter 112 of alignment fixture 100 and susceptor outer edge 212 in response to alignment fixture 100 being disposed in or on, or coupled to, spacer plate 200.

In various embodiments, an alignment fixture may comprise a fixture positioning component, and/or a spacer plate may comprise a plate positioning component, configured to position the alignment fixture in a desired position within or on the spacer plate. A fixture position component may be any suitable device with any suitable design or configuration, which may be complementary to a plate positioning component. A fixture position component may mate with a plate positioning component in order to position the alignment fixture in a desired position within or on the spacer plate. For example, alignment fixture 100 may comprise one or more fixture positioning components 108, which may be recesses in fixture body 110 through lower surface 118 spanning at least a portion of the thickness of fixture body 110. A fixture positioning component 108 may have a shape complementary to a shape of a plate positioning component 208 of spacer plate 200. Plate positioning component 208 of spacer plate 200 may comprise a protrusion from an inner wall (e.g., first inner wall 224 and/or second inner wall 234) and/or an inner surface (e.g., first inner surface 226 and/or second inner surface 236) of spacer plate 200. Accordingly, plate positioning component 208 may be received within a fixture positioning component 108, thereby, positioning alignment fixture 100 in a desired position in and/or on, and with respect to, spacer plate 200.

A height of the alignment fixture (the distance between the upper surface and the lower surface) may be such that the measuring protrusions protruding over the susceptor are not in contact with the susceptor. For example, the height of alignment fixture 100 (the distance between upper surface 116 and lower surface 118) may be such that in response to lower surface 118 resting on a surface of spacer plate 200 (e.g., first inner surface 226 and/or second inner surface 236), measuring protrusions 150 may not contact susceptor 210. That is, measuring protrusions 150 may be disposed over susceptor 210 such that there is a gap between a lower surfaces 156 of measuring protrusions 150 and a top surface of susceptor 210 (a surface of susceptor 210 configured to support a substrate).

As discussed herein, the shape of a susceptor may be complementary to the inner space of an alignment fixture (and/or the shape at least partially defined by the inner perimeter). Therefore, for example, susceptor 210 may be disposed in inner space 120 of alignment fixture 100. In various embodiments, the inner space (or the shape at least partially defined by the inner perimeter) of an alignment fixture may comprise the same shape as the a susceptor, but with larger proportions, so the susceptor may be disposed in the inner space. In various embodiments, the susceptor of a reaction system may be disposed in the inner space of an alignment fixture such that the shape of the susceptor (defined by the susceptor outer edge) is concentric with the shape at least partially defined by the inner perimeter of the alignment fixture. Thus, in response to the susceptor being positioned concentrically with the shape at least partially defined by the inner perimeter of the alignment fixture, the space between the susceptor outer edge and the alignment fixture inner perimeter may be substantially equal along the alignment fixture inner perimeter and/or susceptor outer edge (as used herein, “substantially” means a difference of plus or minus 5% or 10%).

The desired position of a susceptor in a spacer plate may be such that the space between the susceptor outer edge and an inner wall of the spacer plate (e.g., a first or second inner wall) is substantially uniform or equal along the spacer plate inner wall and/or susceptor outer edge. Such positioning of the susceptor may allow processing to occur in a reaction chamber (e.g., a reaction chamber enclosed by spacer plate 200 and lid 250 which may couple to spacer plate 200) that achieves desired results. For example, a centered susceptor may allow uniform distribution of heat to the susceptor and/or substrate disposed thereon, uniform exposure of a substrate on the susceptor to reactant gases (e.g., to achieve uniform material deposition and/or etching), uniform, constant, or regulated airflow and circulation with the reaction chamber, and/or the like.

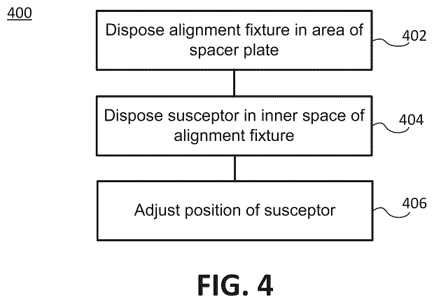

Accordingly, an alignment fixture may be configured to aid in centering the susceptor (and/or a heater, for example, coupled to the susceptor) within a plate interior space of a spacer plate. The plate interior space may be the space defined by the inner walls and/or surfaces of the spacer plate (e.g., the space in spacer plate 200 defined by first inner wall 224 and, first inner surface 226, second inner wall 234, and/or second inner surface 236). With additional reference to method 400 in FIG. 4, to center susceptor 210 within a plate interior space of spacer plate 200, alignment fixture 100 may be disposed in or on, and/or coupled to, spacer plate 200. In various embodiments, an alignment fixture may be at least partially disposed within an area of a spacer plate (step 402) (e.g., upper area 232 and/or lower area 222). As discussed herein, alignment fixture 100 may be so disposed in/on or coupled to spacer plate 200 such that outer perimeter 114 of alignment fixture 100 may be proximate, adjacent to, and/or contiguous with an inner wall of spacer plate 200 (e.g., second inner wall 234). In various embodiments, the shape of the alignment fixture defined by the outer perimeter may be complementary to the shape defined by an inner wall of the spacer plate. Therefore, the alignment fixture outer perimeter may be in contact with such inner wall of the spacer plate so that the alignment fixture is disposed in a desired position (e.g., such that the shape at least partially defined by the inner perimeter of the alignment fixture is concentric with the plate interior space of the spacer plate). For example, outer perimeter 114 of alignment fixture 100 may be disposed against second inner wall 234 of spacer plate 200 such that the plate interior space defined by second inner wall 234 is concentric with inner space 120 of alignment fixture 100.

In response to the alignment fixture being disposed in or on, and/or coupled to, the spacer plate, susceptor 210 may be disposed in inner space 120 of alignment fixture 100 (step 404). Susceptor 210 may be disposed in inner space 120 of alignment fixture 100 as a result of step 402 (because susceptor 210 was already disposed in and/or coupled to spacer plate 200), or susceptor 210 may be disponed in inner space 120 of alignment fixture 100 after alignment fixture 100 is disposed in or on spacer plate 200.

Measuring protrusions of the alignment fixture may extend toward the inner space of the alignment fixture, extending over the susceptor. Therefore, the outer edge of the susceptor may pass under the measuring protrusion, intersecting a plane defined by the first and second surfaces of a measuring protrusion. For example, susceptor outer edge 212 may intersect planes defined by first side 151 and second side 152 of measuring protrusions 150. Therefore, a position of the susceptor outer edge (a portion thereof proximate the measuring protrusions and/or where the susceptor outer edge passes under the measuring protrusions) relative to the measuring protrusion(s) and/or the indicator(s) disposed thereon may be visible and determined. In response to the position of the susceptor outer edge relative to a first measuring protrusion and/or the indicator disposed thereon differing from the position of the susceptor outer edge relative to a second measuring protrusion and/or the indicator disposed thereon, the susceptor may be determined to be off-center. In response, a position of the susceptor may be adjusted (step 406). For example, a first position of susceptor outer edge 212 relative to the pluralities of indicators 160 on a first measuring protrusion 150 may be determined (e.g., by observing susceptor outer edge 212 at a side of the first measuring protrusion 150 and/or through protrusion void 157). A second position of susceptor outer edge 212 relative to the pluralities of indicators 160 on a second measuring protrusion 150 may be determined. The determined positions may comprise the indicator of the pluralities of indicators 160 at which, or closest to which, susceptor outer edge 212 is positioned for both of measuring protrusions 150 (e.g., when susceptor outer edge 212 passes under each of measuring protrusions 150). If the first position determined is different from the second position determined, susceptor 210 may be adjusted within spacer plate 200 and inner space 120 to make the first position and second position substantially equal. For example, if the portion of susceptor outer edge 212 passes under a first of the measuring protrusions 150 proximate a fourth indicator of the plurality of indicators 160, and if the portion of susceptor outer edge 212 passes under a second of the measuring protrusions 150 proximate a fifth indicator of the plurality of indicators 160, susceptor 210 may not be centered within the plate interior space of spacer plate 200. Therefore, susceptor 210 may be adjusted in inner space 120 of alignment fixture 100 (e.g., such that the portions of susceptor outer edge 212 pass under each measuring protrusion 150 proximate the same indicator, or the same distance from an indicator, or the like).

Benefits and other advantages have been described herein with regard to specific embodiments. Furthermore, the connecting lines shown in the various figures contained herein are intended to represent exemplary functional relationships and/or physical couplings between the various elements. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements of the disclosure. The scope of the disclosure is accordingly to be limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

Systems, methods and apparatus are provided herein. In the detailed description herein, references to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. 112 (f), unless the element is expressly recited using the phrase “means for.” As used herein, two or more components being “coupled” may mean a physical, mechanical, fluid, and/or electrical coupling, as may be dictated by the respective context. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method, comprising:
disposing an alignment fixture at least partially within an area between a susceptor outer edge of a susceptor and a spacer plate inner wall of a spacer plate of a reactor system, wherein the susceptor is disposed within an inner space of the alignment fixture at least partially defined by an inner perimeter of the alignment fixture, wherein a first measuring protrusion protruding from a fixture body of the alignment fixture is disposed over the outer edge of the susceptor; and
adjusting a position of the susceptor such that the susceptor is disposed in a desired position relative to the inner perimeter of the alignment fixture.

2. The method of claim 1, wherein the alignment fixture comprises a second measuring protrusion protruding from the fixture body and disposed over the outer edge of the susceptor.

3. The method of claim 2, wherein the adjusting the position of the susceptor comprises positioning the susceptor such that the susceptor is positioned the same distance along the first measuring protrusion relative to the inner perimeter of the alignment fixture as along the second measuring protrusion relative to the inner perimeter of the alignment fixture.

4. The method of claim 2, wherein the alignment fixture is physically separate from the spacer plate.

5. The method of claim 1, wherein the first measuring protrusion comprises a first plurality of graduation marks disposed between the fixture body and a first measuring protrusion end of the first measuring protrusion.

6. The method of claim 2, wherein the second measuring protrusion comprises a second plurality of graduation marks disposed between the fixture body and a second measuring protrusion end of the second measuring protrusion.

7. The method of claim 2, wherein each of the first measuring protrusion and the second measuring protrusion comprises a plurality of graduation marks disposed between the fixture body and a measuring protrusion end.

8. The method of claim 2, wherein the second measuring protrusion is disposed between 30 degrees and 160 degrees apart from the first measuring protrusion relative to a center of the inner space of the alignment fixture.

9. The method of claim 1, wherein the spacer plate comprises a plate positioning component, wherein the alignment fixture comprises a fixture positioning component, wherein the disposing the alignment fixture at least partially within the area between the susceptor outer edge of the susceptor and the spacer plate inner wall of spacer plate comprises the fixture positioning component engaging with the plate positioning component.
